(19) United States
(12) Patent Application Publication
(10) Pub. No.: US 2023/0402361 A1
(43) Pub. Date: Dec. 14, 2023

(54) SEMICONDUCTOR DEVICE INCLUDING REINFORCING BLOCKS

(71) Applicant: WESTERN DIGITAL TECHNOLOGIES, INC., San Jose, CA (US)

(72) Inventors: Shenghua Huang, Shanghai (CN); Binbin Zheng, Shanghai (CN); Shaopeng Dong, Shanghai (CN); Songtao Lu, Shanghai (CN); Rui Guo, Shanghai (CN); Yangming Liu, Shanghai (CN); Bo Yang, Milpitas, CA (US); Ning Ye, San Jose, CA (US)

(73) Assignee: WESTERN DIGITAL TECHNOLOGIES, INC., San Jose, CA (US)

(21) Appl. No.: 17/840,322

(22) Filed: Jun. 14, 2022

(51) Int. Cl. H01L 23/498; H01L 23/12; H01L 23/31; H01L 25/065; G06K 19/077; H01L 23/00

(52) U.S. Cl. CPC H01L 23/49838; H01L 23/12; H01L 23/3107; H01L 25/0657; G06K 19/07732; H01L 24/48; H01L 2225/06562; H01L 2924/3512; H01L 2924/1511; H01L 2224/48135

(57) ABSTRACT

A semiconductor device includes a substrate, semiconductor dies on the substrate, molding compound and reinforcing blocks on the substrate. The reinforcing blocks may be provided at positions on the substrate where mechanical stresses develop in the device during singulation, such as at curves and/or discontinuous points around the outline of the substrate, to add strength to the substrate.

### BACKGROUND

The strong growth in demand for portable consumer electronics is driving the need for high-capacity storage devices. Non-volatile semiconductor memory devices are now widely used to meet the ever-growing demands on digital information storage and exchange. Their portability, versatility and rugged design, along with their high reliability and large capacity, have made such memory devices ideal for use in a wide variety of electronic products, including for example digital cameras, digital music players, video game consoles, computer SSDs, PDAs and cellular telephones.

While many varied packaging configurations are known, flash memory semiconductor devices may in general be assembled as system-in-a-package (SIP) or multichip modules (MCM), where a plurality of semiconductor dies are mounted and interconnected to an upper surface of substrate. The substrate may in general include a rigid, dielectric base having a conductive layer etched on one or both sides. Once the dies are mounted and electrically connected to each other and the substrate, this assembly may be encapsulated in a molding compound.

One popular semiconductor memory package is a MicroSD card, which may be removably inserted into the slot of a host device. The MicroSD card has an outline having curves and straight edges. In order to singulate cards that are formed simultaneously from the same substrate, lasers are often used to cut the curved portions of the package outline, and saw blades are used to cut the straight portions of the package outline.

It has been determined that the laser generates mechanical stresses in the semiconductor package, and that cracks can form in the substrate at the beginning and/or end of laser cuts of the curved portions of the semiconductor package. Cracks can also form at discontinuous points of the package outline (i.e., where lines or curves come together at a non-zero angle). These cracks can sever electrical traces, damage semiconductor dies and otherwise damage or cause failure of the semiconductor package.

Moreover, modern day, high frequency semiconductor packages generate a lot of heat, and it is desirable to provide the molding compound with a high thermal conductivity. However, mold compounds of high thermal conductivity often have less strength, which exacerbates the cracking of the package substrate at curves or discontinuous points.

### DESCRIPTION OF THE DRAWINGS

FIG. 1 is a flowchart of the overall assembly process of a semiconductor device according to embodiments of the present technology.

FIG. 2 is a top view of a panel of substrates used in forming semiconductor devices according to embodiments of the present technology.

FIG. 3 is a top view of a substrate during assembly according to an embodiment of the present technology.

FIG. 4 is a bottom view of a substrate during assembly according to an embodiment of the present technology.

FIG. 5 is a top view of a portion of the substrate panel showing discrete point reinforcing blocks formed or mounted on the substrate according to embodiments of the present technology.

FIG. 6 is a top view of a portion of the substrate panel showing sectional reinforcing blocks formed or mounted on the substrate according to an alternative embodiment of the present technology.

FIG. 7 is a top view of a portion of the substrate panel showing ring reinforcing blocks formed or mounted on the substrate according to a further embodiment of the present technology.

FIG. 8 is a top view of a semiconductor device during assembly according to an embodiment of the present technology.

FIG. 9 is a side view of the semiconductor device shown in FIG. 8.

FIG. 10 is a side view of the semiconductor device shown in FIG. 8 with the reinforcing blocks formed or mounted on a bottom surface of the substrate according to an alternative embodiment of the present technology.

FIG. 11 is a top view of a completed encapsulated semiconductor device according to embodiments of the present technology.

FIG. 12 is a cross-sectional side view of a completed encapsulated semiconductor device according to embodiments of the present technology.

### DETAILED DESCRIPTION

The present technology will now be described with reference to the figures, which in embodiments, relate to a semiconductor device including a substrate, semiconductor dies, molding compound and reinforcing blocks on the substrate. The reinforcing blocks may be provided at positions where mechanical stresses develop in the device, such as at curves and/or discontinuous points around the outline of the substrate.

When the semiconductor device is singulated, the reinforcing blocks add strength to these mechanical stress points to prevent cracking of the substrate during singulation. The reinforcing blocks may be formed or mounted on a top and/or bottom surface of the substrate, at the substrate outline so that portions of the reinforcing blocks remain in the completed semiconductor device when the device is singulated from the substrate panel. The reinforcing blocks further allow a low strength, high thermal conductivity molding compound to be used to improve heat dissipation from the semiconductor device.

It is understood that the present technology may be embodied in many different forms and should not be construed as being limited to the embodiments set forth herein. Rather, these embodiments are provided so that this disclosure will be thorough and complete and will fully convey the technology to those skilled in the art. Indeed, the technology is intended to cover alternatives, modifications and equivalents of these embodiments, which are included within the scope and spirit of the technology as defined by the appended claims. Furthermore, in the following detailed description of the present technology, numerous specific details are set forth in order to provide a thorough understanding of the present technology. However, it will be clear to those of ordinary skill in the art that the present technology may be practiced without such specific details.

The terms “top” and “bottom,” “upper” and “lower” and “vertical” and “horizontal” as may be used herein are by way of example and illustrative purposes only, and are not meant to limit the description of the technology inasmuch as the referenced item can be exchanged in position and orientation. Also, as used herein, the terms “substantially,” “approximately” and/or “about” mean that the specified dimension or parameter may be varied within an acceptable manufacturing tolerance for a given application. In one embodiment, the acceptable manufacturing tolerance is 0.15 mm or alternatively ±2.5% of a given dimension.

For purposes of this disclosure, a connection may be a direct connection or an indirect connection (e.g., via one or more other parts). In some cases, when a first element is referred to as being connected, affixed, mounted or coupled to a second element, the first and second elements may be directly connected, affixed, mounted or coupled to each other or indirectly connected, affixed, mounted or coupled to each other. When a first element is referred to as being directly connected, affixed, mounted or coupled to a second element, then there are no intervening elements between the first and second elements (other than possibly an adhesive or melted metal used to connect, affix, mount or couple the first and second elements).

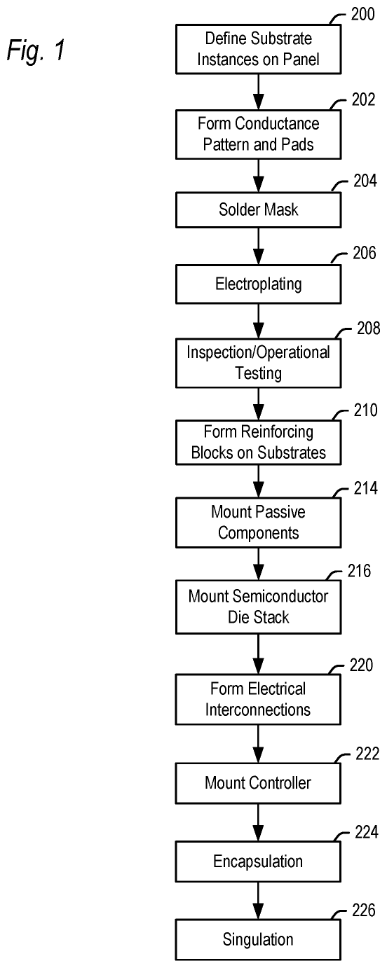

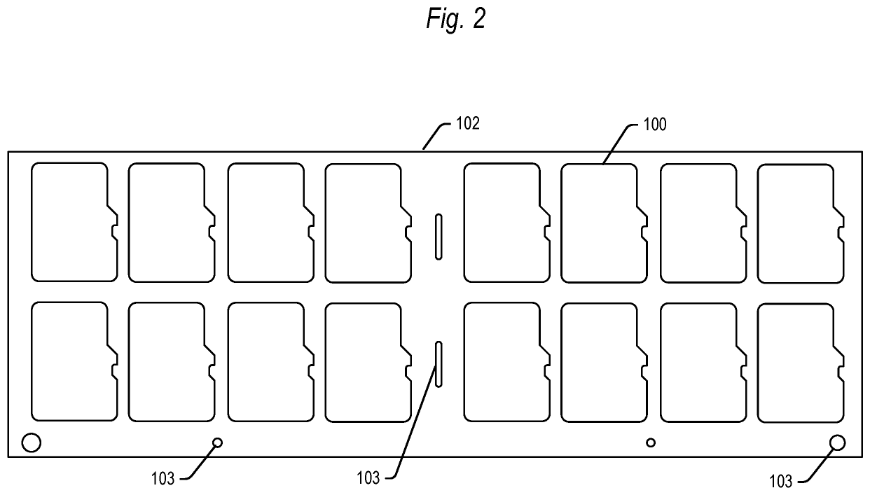

An embodiment of the present technology will now be explained with reference to the flowchart of FIG. 1 and the top and side views of FIGS. 2 through 12. The assembly of a semiconductor device according to the present technology begins with a plurality of substrates 100 formed contiguously on a panel 102 in step 200 as shown in FIG. 2. FIG. 2 shows one representation of a panel 102 of substrates 100, though panel 102 may have a wide variety of other configurations and numbers of substrates 100 in further embodiments. Fiducial marks 103 are provided on the substrate panel 102 to allow machine vision alignment of the substrate panel in a processing tool. Again, the fiducial marks are by way of example only and may vary in other substrate panels.

The substrate 100 is an example of a chip carrier medium provided to transfer signals, data and/or information between one or more semiconductor dies mounted on the chip carrier medium and a host device as explained below. Other examples of chip carrier mediums may be used, including a printed circuit board (PCB), a leadframe or a tape automated bonded (TAB) tape. The substrate may be formed of one or more core layers, each sandwiched between two conductive layers. The conductive layers may be formed of copper or copper alloys, plated copper or plated copper alloys, Alloy 42 (42Fe/58Ni), copper plated steel, or other metals and materials suitable for use on substrate panels. The one or more core layers may be formed of various dielectric materials such as for example, polyimide laminates, epoxy resins including FR4 and FR5, bismaleimide triazine (BT), and the like. The one or more core layers may be ceramic or organic in alternative embodiments.

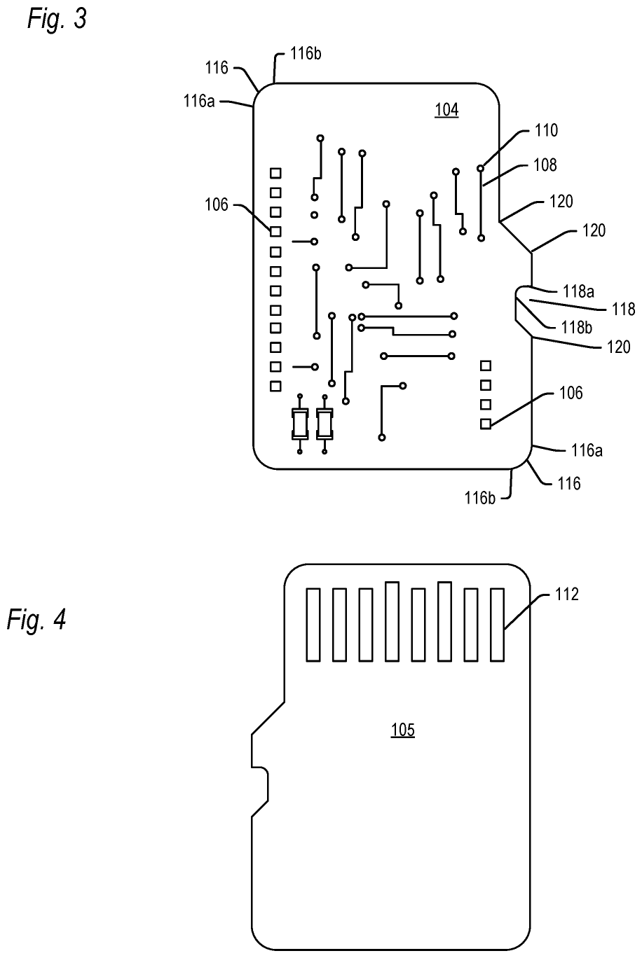

The two or more conductive layers may be etched into conductance patterns comprising electrical connectors in step 202. These electrical connectors may be formed in one or both of the first major planar surface 104 and the second major planar surface 105 of the substrate 100, shown in the views of the substrate 100 in FIGS. 2 and 3, respectively. In one example, the electrical connectors in the first major surface 104 may include contact pads 106 for physically and electrically attaching different electronic components to the substrate, such as memory dies and a controller die as explained below. The electrical connectors in surface 104 may further include electrical traces 108 and through-hole vias 110 electrically interconnecting conductance patterns of the different conductive layers of substrate 100.

As shown in the bottom view of FIG. 3, the electrical connectors in the second major planar surface 105 may further include contact fingers 112 configured to physically mate with pins of a host device slot (not shown) to enable data exchange between the host device and the semiconductor device of the present technology. The second major surface 105 may additionally include contact pads 106, traces 108 and/or vias 110 (not shown) in further embodiments.

The substrate 100 may undergo a variety of further processing steps, including solder masking (step 204), electroplating of exposed contact pads (step 206), inspection and operational testing (step 208). Additional or alternative processing steps are contemplated.

In one example, the outline of each substrate may have straight sections and curved sections which meet each other. For example, FIG. 2 shows curves at corners 116 of the substrate 100 and at a notch 118. Each corner 116 includes a beginning 116a and an end 116b. Notch 118 includes a curved section having a beginning 118a and an end 118b. The outline also includes curved and/or straight sections that come together at an angle (referred to herein as points of discontinuities). Some of these points of discontinuities 120 are labeled in FIG. 2. In the example shown, the substrate may be for a MicroSD (Standard Digital) card. However, it is understood that the substrate 100 may have a variety of other shapes, including curved sections, straight sections and/or points of discontinuities.

In accordance with aspects of the present technology, reinforcing blocks 122 may be formed on the substrate in step 210. As noted in the Background section and discussed below, mechanical stress points may develop in the substrates 100 when the substrates are singulated from the panel 102. In order to reinforce these points and help dissipate the stresses to prevent cracking of the substrate, the substrate 100 may built up at (at least) the points where mechanical stresses occur in the substrate. In one embodiment, these mechanical stress points occur at the beginning and end of laser-cut curved sections of the outline of the substrate (116a, 116b, 118a, 118b), and possibly along the curved sections as well (116). Mechanical stresses may also or alternatively occur at points of discontinuities (120).

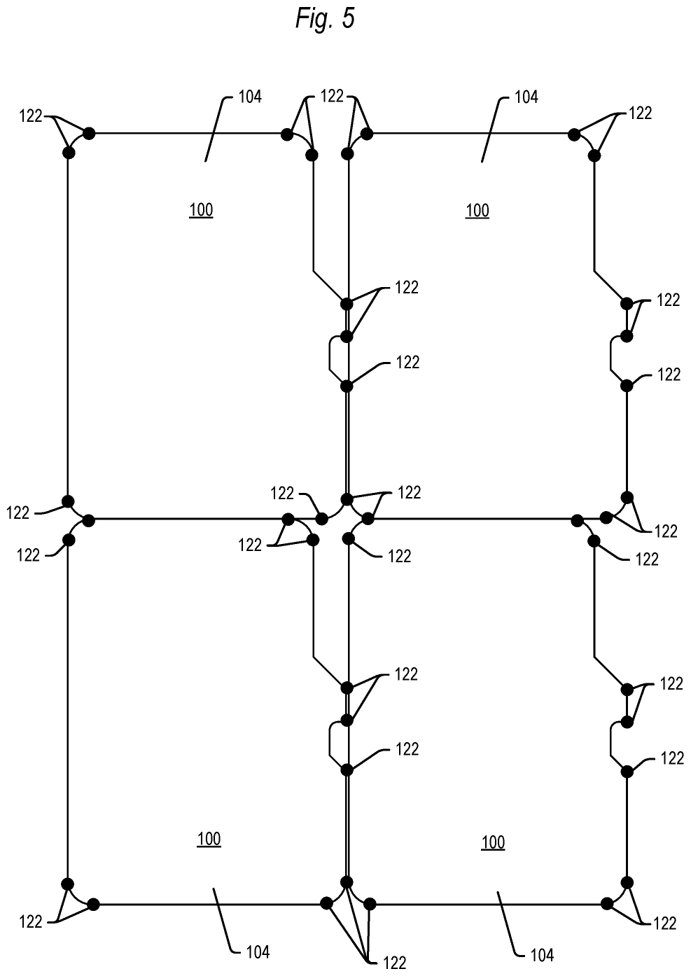

FIGS. 5-7 illustrate different embodiments of substrate 100 including reinforcing blocks 122. In FIG. 5, the reinforcing blocks 122 (some of which are numbered) are applied at discrete points specifically over the mechanical stress points. In this embodiment, the stress points are at the beginning and end of curved sections (116a, 116b, 118a, 118b), and (possibly) at points of discontinuities (120). The reinforcing blocks 122 in the embodiment of FIG. 5 may for example be circular with a diameter of 0.1 mm to 0.2 mm. However, the reinforcing blocks 122 of the embodiment of FIG. 5 may be different shapes (including squares) and may be larger or smaller than that in further embodiments. The discrete point reinforcing blocks may be applied to the substrate 100 at positions that do not interfere or conflict with the positions of other components on the surface 104 of the substrate 100, which components are added as explained below.

The discrete point reinforcing blocks 122 in FIG. 5 (and other) embodiments may be formed of a metal, such as Aluminum, Copper or alloys thereof. Blocks 122 may alternatively be formed of various polymers, including for example any of various acrylics, epoxies, polyurethanes, silicones, polyimides, fluorocarbons, benzocyclobutenes (BCB), and p-polyxylylenes. The blocks 122 may be formed of other materials including for example various resins including for example epoxy resin and Phenol resin and various silicas, including for example fused silica and crystalline silica. Other materials are contemplated which can be used for reinforcing blocks 122 in any of the embodiments described herein. The reinforcing blocks of FIGS. 5-7 may be applied in various processes, including for example various photolithographic processes, or as discrete elements adhered to the surface of the substrate 100 as by an adhesive or ultrasonic welding.

As explained below, a molding compound may be applied to the first major surface 104 of substrate 100, which molding compound may extend for example 0.5 mm above surface 104. The discrete point reinforcing blocks 122 in FIG. 5 (and other) embodiments may extend above the substrate to a height smaller than or equal to a height of the molding compound above the first major planar surface 104 of the substrate 100. In one embodiment, the reinforcing blocks may be 501 μm to 0.5 mm above the surface 104, though the reinforcing blocks may be smaller than that, or larger than that (depending on the thickness of the molding compound). The reinforcing blocks 122 may be coated to prevent oxidation and/or to promote adhesion with the molding compound applied as described below. The coating may be omitted in further embodiments.

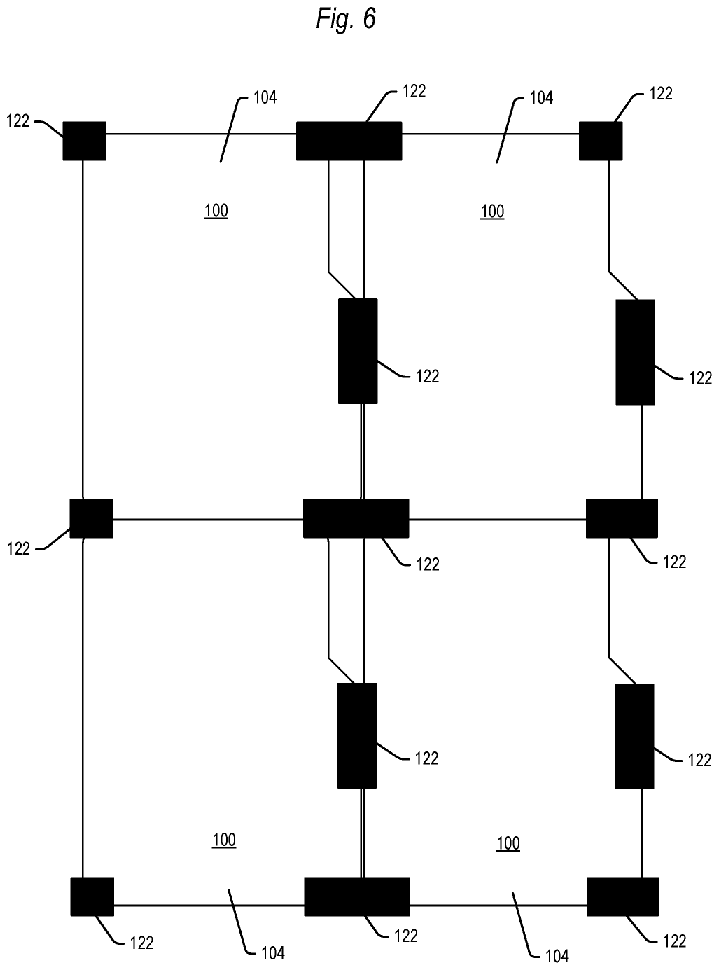

Instead of discrete point reinforcing blocks, the reinforcing blocks 122 may be applied in sections, each covering multiple stress points for example at the beginning and end of a curve. This embodiment is shown in FIG. 6. The sectional reinforcing blocks 122 may each also cover entire curves, or an entire curve as well as one or more points of discontinuities. The length and width of the sectional reinforcing blocks 122 may vary, depending on how many mechanical stress points each covers, but in one example, a sectional reinforcing block 122 may be 2 mm long and 1 mm wide. The sectional reinforcing blocks 122 may be square or rectangular as shown, but they may be other shapes including circular, oval or square or rectangle with rounded edges. The sectional reinforcing blocks 122 may otherwise have the same properties as the discrete point reinforcing blocks 122 described above.

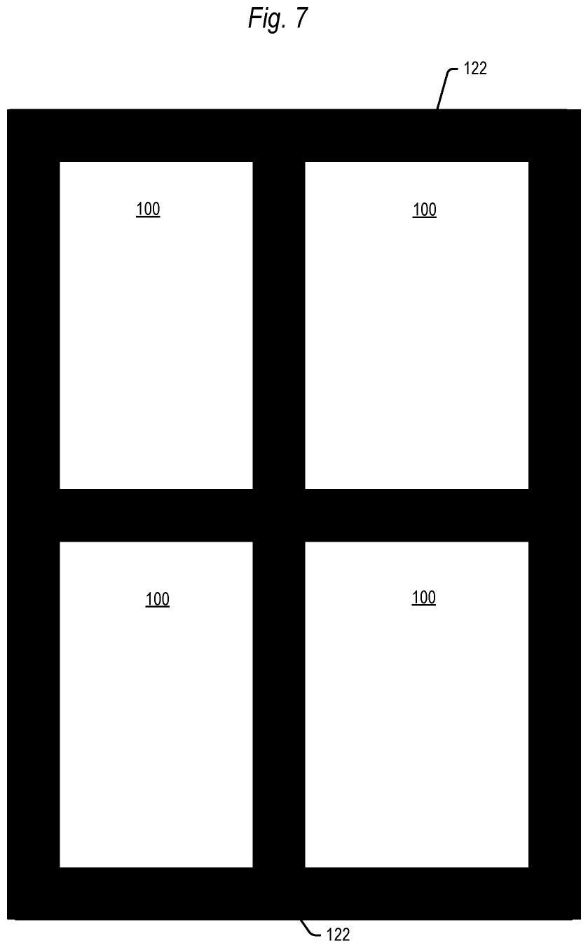

As a further example, the reinforcing block 122 may be applied as a ring around the entire outline of each substrate 100, as shown in FIG. 7. The ring reinforcing block 122 may have a width of between 1 mm and 2 mm, though the width may be smaller or larger than this in further embodiments, with the provision that the ring reinforcing block 122 not interfere or conflict with the positions of other components on the surface of the substrate, which components are added as explained below. While the ring reinforcing block 122 is shown as a single continuous ring around all four edges of each substrate 100, the reinforcing blocks may be applied in discrete sections (such as in FIG. 6) covering a single edge, two adjoining or opposed edges, or three edges of the substrate 100. The ring reinforcing block 122 may otherwise have the same properties as the discrete point and sectional reinforcing blocks 122 described above.

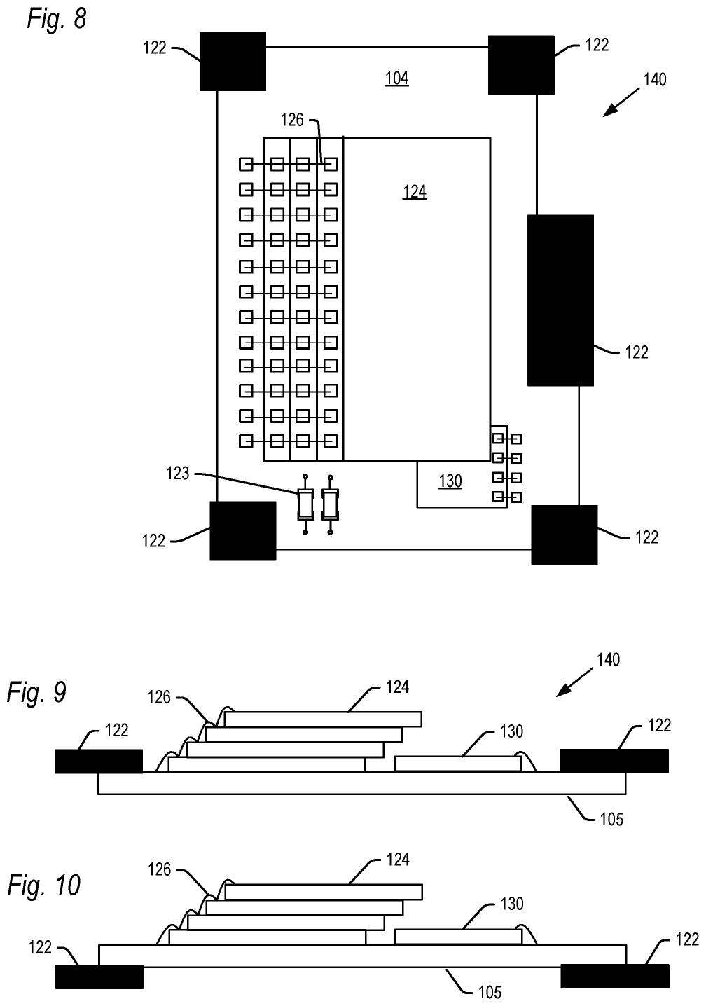

Once the reinforcing block or blocks have been formed on the substrate 100, components may be mounted on the substrate to form a completed semiconductor device 140. For example, in step 214, passive components 123 may be affixed to the substrate 100 as shown in the top view of FIG. 8. The one or more passive components may include for example one or more capacitors, resistors and/or inductors, though other components are contemplated. The passive components 123 shown are by way of example only, and the number, type and position may vary in further embodiments.

In step 216, one or more semiconductor dies may be mounted on the first major planar surface 104 of the substrate 100. For example, FIGS. 8 and 9 show top and side views, respectively, of semiconductor dies 124 stacked on substrate 100. The semiconductor dies 124 may for example be memory dies such as 2D NAND flash memory or 3D BiCS (Bit Cost Scaling), V-NAND or other 3D flash memory, but other types of dies 124 may be used. These other types of semiconductor dies include but are not limited to RAM such as an SDRAM, DDR SDRAM, LPDDR and GDDR.

Where multiple semiconductor dies 124 are included, the semiconductor dies 124 may be stacked atop each other in an offset stepped configuration to form a die stack. The number of dies 124 shown in the stack is by way of example only, and embodiments may include different numbers of semiconductor dies, including for example 1, 2, 4, 8, 16, 32 or 64 die. There may be other numbers of dies in further embodiments. The one or more dies may be affixed to the substrate and/or each other using a die attach film. As one example, the die attach film may be cured to a B-stage to preliminarily affix the dies 124 in the stack, and subsequently cured to a final C-stage to permanently affix the dies 124 to the substrate 100.

In step 220, the semiconductor dies 124 may be electrically interconnected to each other and to the substrate 100. FIGS. 8 and 9 show views of bond wires 126 being formed between corresponding die bond pads on respective dies 124 down the stack, and then bonded to contact pads 106 on a surface of substrate 100. The wires 126 may be bonded by a ball-bonding technique, but other wire bonding techniques are possible. The semiconductor dies 124 may be electrically interconnected to each other and the substrate 100 by other methods in further embodiments, including by through-silicon vias (TSVs) or flip-chip bonding.

In step 222, a controller die 130 may be affixed on in the first major planar surface 104 of substrate 100 as shown in FIGS. 8 and 9. Controller die 130 may for example be an ASIC for controlling transfer of signals and data to and from the semiconductor dies 124. The controller die 130 may be wire bonded to contact pads 106 of the substrate 100 as shown, or it may be flip-chip mounted in further embodiments.

FIGS. 8 and 9 also show the reinforcing blocks 122. In the example shown the reinforcing blocks 122 are sectional reinforcing blocks, but they may be any of the reinforcing blocks described herein. FIGS. 8 and 9 also show the reinforcing blocks extending beyond the outline of a single substrate 100. That is because, at this point in the fabrication, the substrates 100 are still part of panel 102. The portions of the reinforcing blocks 122 extending beyond the outline of the illustrated substrate 100 may be provided on mechanical stress points of neighboring substrates (not shown in FIGS. 8 and 9).

In the embodiments shown in FIGS. 5-9, the reinforcing blocks 122 may be formed on the first major planar surface 104. However, in a further embodiment shown in the side view of FIG. 10, the reinforcing blocks 122 may be formed on the second major planar surface 105. In further embodiments, the reinforcing blocks may be formed on both of the major planar surfaces 104 and 105. In such an embodiment, a single mechanical stress point may reinforcing blocks aligned with each other over the mechanical stress point on both the top and bottom surfaces of the substrate. In such an embodiment, the pattern of reinforcing blocks 122 on the first major planar surface 104 may be the same as the pattern of reinforcing blocks 122 on the second major planar surface 105. However, in further embodiments, some or all of the positions of the reinforcing blocks on the first major planar surface 104 may be different than the positions of the reinforcing blocks on the second major planar surface 105. This embodiment may be useful in placing reinforcing blocks 122 at mechanical stress points while also avoiding interference or conflict with structure on one side or the other of the substrate 100.

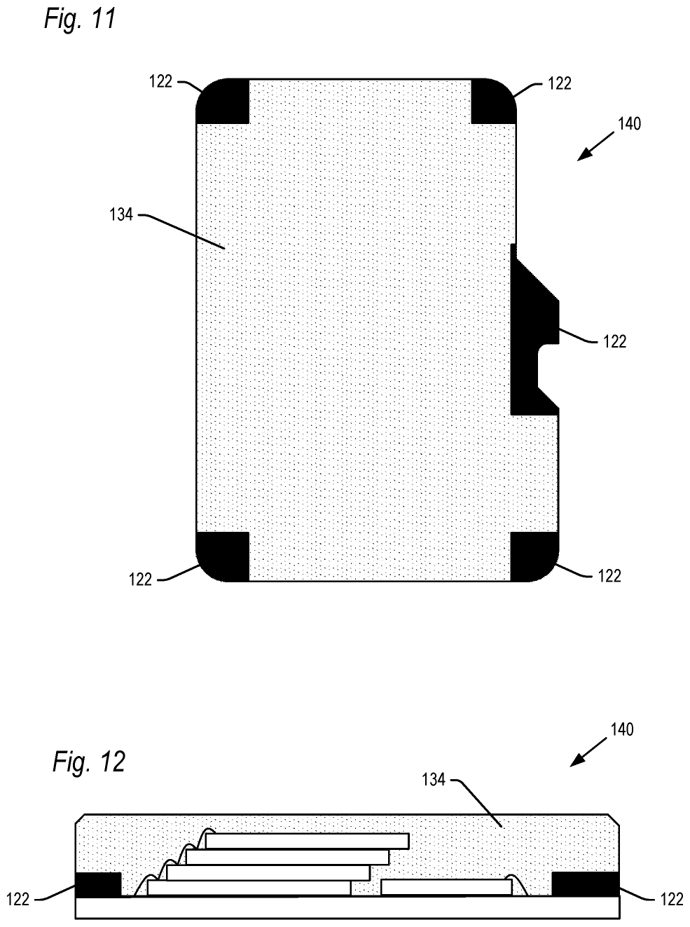

In step 224, the panel 102 of semiconductor devices 140 may be encapsulated in a mold compound 134 as shown in the top and side views of FIGS. 11 and 12. Mold compound 134 may include for example solid epoxy resin, Phenol resin, fused silica, crystalline silica, carbon black and/or metal hydroxide. Other mold compounds are contemplated. As explained below, it is a feature of the present technology that the molding compound may be selected having lower strength but greater heat conduction properties. The mold compound may be applied by various known processes, including by FFT (flow free thin) molding, compression molding, transfer molding or injection molding techniques.

After assembly and encapsulation of the semiconductor devices 140, the semiconductor devices 140 may be singulated from each other and panel 102 in step 226 to form individual finished semiconductor devices 140, such as the one shown in the top and side views of FIGS. 11 and 12. The semiconductor devices 140 may be singulated by any of a combination of cutting methods including sawing, water jet cutting, laser cutting, water guided laser cutting, dry media cutting, and diamond coating wire cutting. As shown and described herein, the outline of the semiconductor device may have straight linear segments and curved segments. In embodiments, the curved sections may be cut first, using for example a laser or water jet. The straight segments may thereafter be cut using for example a saw to complete a cut around the entire outline of each semiconductor device 140, separating or singulating the device from the panel 102.

As noted in the Background section, where the curved sections of the semiconductor device 140 are singulated, mechanical stress points may develop at the beginning and/or end of a cut. Mechanical stresses may also develop along the curve, and/or at points of discontinuity, where two cuts come together at some non-zero angle. The reinforcing blocks 122 function to add strength and rigidity to the semiconductor device 140 at these mechanical stress points during the singulation process and in the completed semiconductor device 140. The material and thickness of the reinforcing blocks 122 may be selected depending on the degree of strength and rigidity desired in the semiconductor device 140. As shown in FIGS. 11 and 12, the cuts pass through the reinforcing blocks at the mechanical stress points, leaving portions of the reinforcing blocks 122 at edges of the completed semiconductor device 140. While the figures show multiple discrete and sectional reinforcing blocks 122, it is conceivable that the substrate 100 include only one discrete or sectional reinforcing blocks 122 in further embodiments.

It is known that controller semiconductor dies generate large amounts of heat, especially when operating at the higher frequencies of present-day memory devices. In embodiments, it is a further feature of the reinforcing blocks 122 that then enable the use of a lower strength, higher heat conduction material as the molding compound 134. In this way, the present technology also improves the ability of the semiconductor device 140 to dissipate heat.

In summary, in one example, the present technology relates to a semiconductor device configured to withstand cracking at one or more mechanical stress points, comprising: a substrate; one or more semiconductor dies mounted on the substrate; electrical interconnections electrically coupling the one or more semiconductor dies to the substrate; molding compound encapsulating the one or more semiconductor dies and electrical interconnections; and one or more reinforcing blocks, mounted on the substrate at the one or more mechanical stress points and severed during singulation of the semiconductor device, the one or more reinforcing blocks configured to add strength and rigidity to the semiconductor device.

In another example, the present technology relates to a semiconductor device singulated from a panel and configured to withstand cracking at one or more mechanical stress points generated during singulation, comprising: a substrate comprising a first major planar surface comprising contact pads configured to receive bond wires, and a second major planar surface, opposite the first major planar surface, the second major planar surface comprising contact fingers configured to couple the semiconductor device to a host device; components mounted on the first major planar surface of the substrate, the components comprising one or more semiconductor dies; bond wires electrically coupling the one or more semiconductor dies to the substrate the contact pads on the first major planar surface of the substrate; molding compound encapsulating the one or more semiconductor dies and bond wires; and one or more reinforcing blocks, the one or more reinforcing blocks mounted at one or more positions on one or more of the first and second major planar surfaces, each of the one or more positions determined to be a position of a mechanical stress point of the one or more mechanical stress points, and each of the one or more positions determined to be a position that does not to interfere with positions of the components, the contact pads and the contact fingers.

In a further example, the present technology relates to a semiconductor device singulated from a panel and configured to withstand cracking at one or more mechanical stress points generated during singulation, comprising: a substrate comprising a first major planar surface comprising contact pads configured to receive bond wires, and a second major planar surface, opposite the first major planar surface, the second major planar surface comprising contact fingers configured to couple the semiconductor device to a host device; components mounted on the first major planar surface of the substrate, the components comprising one or more semiconductor dies; bond wires electrically coupling the one or more semiconductor dies to the substrate the contact pads on the first major planar surface of the substrate; molding compound encapsulating the one or more semiconductor dies and bond wires; and means for strengthening the substrate at the one or more mechanical stress points, the means positioned on one or more of the first and second major planar surfaces that do not interfere with positions of the components, the contact pads and the contact fingers.

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

We claim:

1. A semiconductor device configured to withstand cracking at one or more mechanical stress points, comprising:
a substrate;
one or more semiconductor dies mounted on the substrate;
electrical interconnections electrically coupling the one or more semiconductor dies to the substrate;
molding compound encapsulating the one or more semiconductor dies and electrical interconnections; and
one or more reinforcing blocks, formed on the substrate at the one or more mechanical stress points, the one or more reinforcing blocks configured to add strength and rigidity to the semiconductor device.

2. The semiconductor device of claim 1, wherein the one or more reinforcing blocks comprise a plurality of discrete point reinforcing blocks at a plurality of mechanical stress points.

3. The semiconductor device of claim 2, wherein the semiconductor device comprises curved edges along an outline of the semiconductor device, and wherein the plurality discrete point reinforcing blocks are provided at one or more of a beginning of a curve and an end of a curve.

4. The semiconductor device of claim 2, wherein the semiconductor device comprises one or more points of discontinuity where two or more edges along an outline of the semiconductor device come together at discontinuous angles, and wherein one or more discrete point reinforcing blocks of the plurality discrete point reinforcing blocks are provided at the one or more points of discontinuity.

5. The semiconductor device of claim 1, wherein the one or more reinforcing blocks comprise one or more sectional reinforcing blocks, a sectional reinforcing block of the one or more sectional reinforcing blocks covering a plurality of mechanical stress points.

6. The semiconductor device of claim 5, wherein the semiconductor device comprises curved edges along an outline of the semiconductor device, and wherein the sectional reinforcing block covers a curved edge including a first point where the curved edge begins and second point where the curved edge ends.

7. The semiconductor device of claim 6, wherein the semiconductor device comprises one or more points of discontinuity where two or more edges along an outline of the semiconductor device come together at discontinuous angles, and wherein sectional reinforcing block further covers the one or more points of discontinuity.

8. The semiconductor device of claim 1, wherein the one or more reinforcing blocks comprise one or more ring reinforcing blocks covering at least an entire side of the semiconductor device and covering a plurality of mechanical stress points.

9. The semiconductor device of claim 8, wherein the ring reinforcing block is provided around an entire outline of the semiconductor device.

10. The semiconductor device of claim 1, wherein the substrate comprises a first major planar surface and a second major planar surface opposite the first major planar surface, wherein both of the one or more semiconductor dies and the one or more reinforcing blocks are mounted on the first major planar surface.

11. The semiconductor device of claim 1, wherein the substrate comprises a first major planar surface and a second major planar surface opposite the first major planar surface, wherein the one or more semiconductor dies are mounted on the first major planar surface and the one or more reinforcing blocks are mounted on the second major planar surface.

12. The semiconductor device of claim 11, wherein the one or more reinforcing blocks further comprise at least one reinforcing block on the first major planar surface of the substrate.

13. The semiconductor device of claim 11, wherein the at least one reinforcing block on the first major planar surface aligns with a reinforcing block of the plurality of reinforcing blocks on the second major planar surface of the substrate.

14. The semiconductor device of claim 1, wherein the one or more reinforcing blocks is formed of one of a metal and a polymer.

15. A semiconductor device singulated from a panel and configured to withstand cracking at one or more mechanical stress points generated during singulation, comprising:
a substrate comprising a first major planar surface, a second major planar surface opposite the first major planar surface, the substrate further comprising contact pads configured to receive an electrical connection and contact fingers configured to couple the semiconductor device to a host device;
components mounted on the first major planar surface of the substrate, the components comprising one or more semiconductor dies, wherein the components are electrically connected to the contact pads on the first major planar surface of the substrate;
molding compound encapsulating the one or more semiconductor dies and bond wires; and
one or more reinforcing blocks, the one or more reinforcing blocks mounted at one or more positions on one or more of the first and second major planar surfaces, each of the one or more positions determined to be a position of a mechanical stress point of the one or more mechanical stress points, and each of the one or more positions determined to be a position that does not interfere with positions of the components, the contact pads and the contact fingers.

16. The semiconductor device of claim 15, wherein the semiconductor device is a MicroSD card.

17. The semiconductor device of claim 15, wherein the one or more reinforcing blocks are all provided on the first major planar surface.

18. The semiconductor device of claim 15, wherein the semiconductor device comprises one or more curved edges, a reinforcing block of the one or more reinforcing blocks provided at at least one of a beginning of a curved edge of the one or more curved edges and an end of the curved edge.

19. The semiconductor device of claim 15, wherein the semiconductor device further comprises a discontinuity point where two edges of the semiconductor device come together at a discontinuous angle, the reinforcing block of the one or more reinforcing blocks further provided at the discontinuity point.

20. A semiconductor device singulated from a panel and configured to withstand cracking at one or more mechanical stress points generated during singulation, comprising:
a substrate comprising a first major planar surface comprising contact pads, a second major planar surface, opposite the first major planar surface, and contact fingers configured to couple the semiconductor device to a host device;
components mounted on the first major planar surface of the substrate, the components comprising one or more semiconductor dies, wherein the components are electrically coupled to the substrate contact pads on the first major planar surface of the substrate;
molding compound encapsulating the one or more semiconductor dies and the electrical connections between the dies and the contact pads; and
means for strengthening the substrate at the one or more mechanical stress points, the means positioned on one or more of the first and second major planar surfaces that do not interfere with positions of the components, the contact pads and the contact fingers.
